(19) United States
(12) Patent Application Publication
(10) Pub. No.: US 2010/0301315 A1
(43) Pub. Date: Dec. 2, 2010

(54) ORGANIC ELECTROLUMINESCENCE ELEMENT

(75) Inventor: Kensuke MASUI, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/780,581

(22) Filed: May 14, 2010

(30) Foreign Application Priority Data
Jun. 1, 2009 (JP) 2009-132033
Apr. 22, 2010 (JP) 2010-098624

(51) Int. Cl. H01L 51/54

(52) U.S. Cl. 257/40; 257/E51.041

(57) ABSTRACT

To provide an organic electroluminescence element, containing: an anode; a cathode; and at least one organic layer disposed between and the anode and the cathode, the organic layer containing a light-emitting layer, wherein the light-emitting layer contains a host material and a phosphorescent light-emitting material, and the host material contains at least one platinum complex compound containing a tetradentade ligand, expressed by the following general formula 1:

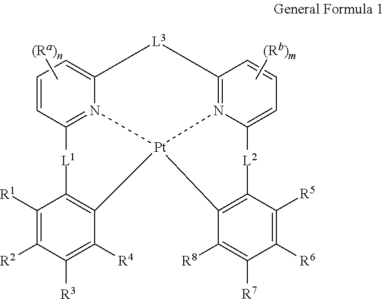

where L¹ to L³ are each a single bond or a bridging group; R¹ to R⁸ are each a hydrogen atom or a substituent, and at least one of R¹ to R⁸ is a phenyl group or a cyano group; R^{a} and R^{b} are each a substituent; and n and m are each an integer of 0 to 3.

### BACKGROUND OF THE INVENTION

1. Field of the Invention

The present invention relates to an organic electroluminescence element (may also referred to as an organic EL element, hereinafter).

2. Description of the Related Art

Organic electroluminescence elements have characteristics such as self-luminescence, high-speed response, and the like, and thus application thereof in flat panel displays has been expected. Especially after information had been made public regarding 2-layer (laminate) elements in which a hole-transport organic thin film (hole-transport layer) and an electron-transport organic thin film (electron-transport layer) are laminated, organic electroluminescence elements have attracted attention as large-scale light-emitting elements capable of emitting at low voltages of 10 V or less. The laminate organic EL element has a basic structure as follows: an anode, a hole-transport layer, a light-emitting layer, an electron-transport layer, and a cathode, in this order. The organic EL element has realized energy efficiency (i.e. by using lower voltages for emitting light) and high emission efficiency due to the aforementioned structure.

In the technology of organic electroluminescence elements, various studies have been conducted to realize higher energy efficiency and higher emission efficiency. For example, there has been proposed an organic electroluminescence element in which a host material and a light-emitting material are contained in a light-emitting layer, and the host material contains a certain Pt complex (see Japanese Patent Application Laid-Open (JP-A) No. 2006-332622).

According to the technique disclosed in JP-A No. 2006-332622, it is possible to improve the energy saving and emission efficiency to a certain degree. However, the current situation is that further improvements in energy efficiency and emission efficiency are desired.

### BRIEF SUMMARY OF THE INVENTION

The present invention aims at providing an organic electroluminescence element that can maintain high emission efficiency while lowering a driving voltage thereof.

As a result of the diligent researches and studies conducted by the present inventors for solving the problems in the art, the present inventors have come to the insights that a platinum complex compound containing a tetradentate ligand for use in the present invention has high electron-transporting performance. The use thereof as a host material enables significantly low driving voltage. Additionally, the use of the platinum complex compound (containing the tetradentate ligand) together with a hole-transporting host material as a mixed host realizes lowered driving voltage as well as high emission efficiency.

The present invention has been made based upon the aforementioned insight of the present inventors, and means for solving the problems are as follows.

<1> An organic electroluminescence element, containing:

an anode;

a cathode; and

at least one organic layer disposed between the anode and the cathode, the organic layer including a light-emitting layer,

wherein the light-emitting layer contains a host material and a phosphorescent light-emitting material, and the host material contains at least one platinum complex compound containing a tetradentade ligand, expressed by the following general formula 1;

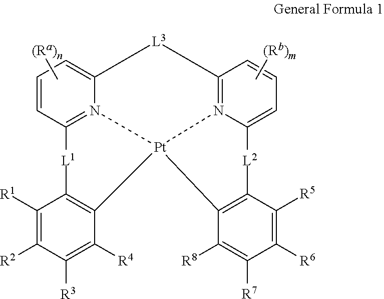

where L¹, L², and L³ are each a single bond or a bridging group; R¹, R², R³, R⁴, R⁵, R⁶, R⁷, and R⁸ are each a hydrogen atom or a substituent, and at least one of R¹ to R⁸ is a phenyl group or a cyano group; R^{a} and R^{b} are each a substituent; and n and m are each an integer of 0 to 3.

<2> The organic electroluminescence element according to <1>, wherein the organic electroluminescence element exhibits a luminescence peak at 550 nm or more.
<3> The organic electroluminescence element according to any of <1> or <2>, wherein the host material contains at least one hole transporting host material.
<4> The organic electroluminescence element according to any one of <1> to <3>, wherein the phosphorescent light-emitting material is a compound expressed by any of the following general formulae 2 to 4;

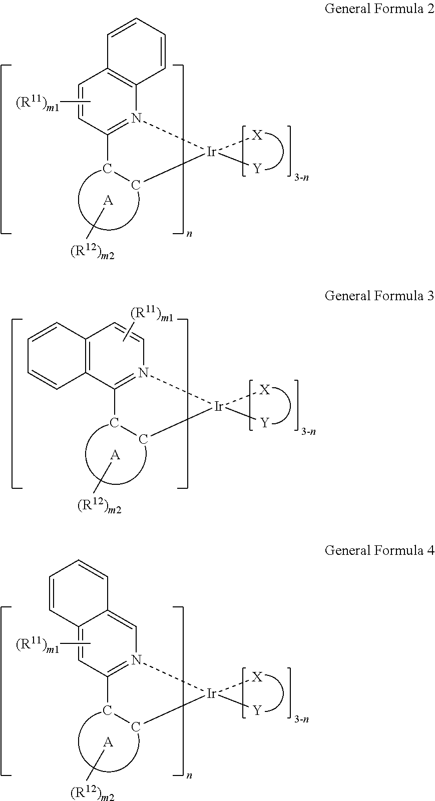

where n is an integer of 1 to 3; X-Y represents a bidentate ligand; a ring A is a ring structure which may contain at least one selected from the group consisting of a nitrogen atom, a sulfur atom, and an oxygen atom; R¹¹ is a substituent, m1 is an integer of 0 to 6, and in the case where m1 is 2 or more, a plurality of R¹¹s adjacent to each other may bond to form a ring, which may contain at least one selected from the group consisting of a nitrogen atom, a sulfur atom, and an oxygen atom, and may have further one or more substituents; R¹² is a substituent, m2 is an integer of 0 to 4, and in the case where m2 is 2 or more, a plurality of R¹²s adjacent to each other may bond to form a ring, which may contain at least one selected from the group consisting of a nitrogen atom, a sulfur atom, and an oxygen atom, and may further contain one or more substituents; R¹¹ and R¹² may bond to each other to form a ring, which may contain at least one selected from the group consisting of a nitrogen atom, a sulfur atom, and an oxygen atom, and may further contain one or more substituents.

The present invention can solve the problems in the art and provide an organic electroluminescence element that, can maintain high emission efficiency while lowering driving voltage.

### BRIEF DESCRIPTION OF THE DRAWING

FIG. 1 is a schematic diagram showing an example of a layer structure of the organic electroluminescence element of the invention.

### DETAILED DESCRIPTION OF THE INVENTION

### Organic Electroluminescence Element

The organic electroluminescence element of the present invention contains an anode, a cathode, and at least one organic layer containing a light-emitting layer, disposed between the anode and the cathode, and may further contain other layers, if necessary.

### <Light-Emitting Layer>

The light-emitting layer contains a host material and a phosphorescent light-emitting material, and may further contain other substances, if necessary.

### -Host Material-

### —Platinum Complex Compound Containing Tetradentate Ligand, Expressed By General Formula 1—

It is preferred that a host material contain at least one platinum complex compound containing a tetradentate ligand expressed by the following general formula 1, and further contain at least one hole-transporting host material.

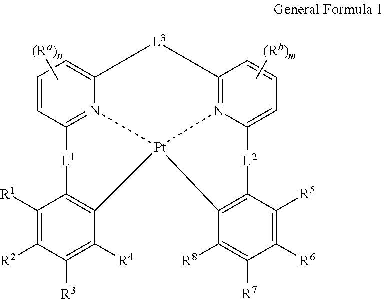

In the general formula 1, L¹, L², and L³ are each a single bond or a bridging group; R¹, R², R³, R⁴, R⁵, R⁶, R⁷, and R⁸ are each a hydrogen atom or a substituent, and at least one of R¹ to R⁸ is a phenyl group or a cyano group; R^{a} and R^{b} are each a substituent; and n and m are each an integer of 0 to 3.

Bridging groups denoted as L¹, L², and L³ may be suitably selected depending on the intended purpose without any restriction. Examples thereof include: an alkylene group such as a methylene group, a dimethylene group, a diisopropylmethylene group, a diphenylmethylene group, an ethylene group, and a tetramethylethylene group; an alkenylene group such as a vinylene group, and a dimethylvinylene group; an alkynylene group such as an ethnylene group; an arylene group such as a phenylene group and a naphthylene group; a heteroarylene group such as a pyridilene group, a pyradilene group, and a quinolilene group; an oxygen bridging group; a sulfur bridging group; a nitrogen bridging group such as a methyl amino bridging group, a phenyl amino bridging group, and a t-butyl amino bridging group; a silicon bridging group; and a bridging group combined thereof, such as an oxylenemethylene group.

Substituents denoted as R¹, R², R³, R⁴, R⁵, R⁶, R⁷, R⁸, R^{a}, and R^{b} may be suitably selected depending on the intended purpose without any restriction. Examples thereof include: an alkyl group, preferably having 1 to 30 carbon atoms, more preferably 1 to 20 carbon atoms, even more preferably 1 to 10 carbon atoms, such as a methyl group, an ethyl group, an isopropyl group, a tert-butyl group, an n-octyl group, an n-decyl group, an n-hexadecyl group, a cyclopropyl group, a cyclopentyl group, and a cyclohexyl group; an alkenyl group, preferably having 2 to 30 carbon atoms, more preferably 2 to 20 carbon atoms, yet more preferably 2 to 10 carbon atoms, such as a vinyl group, an allyl group, a 2-butenyl group, and a 3-pentenyl group; an alkynyl group, preferably having 2 to 30 carbon atoms, more preferably 2 to 20 carbon atoms, even more preferably 2 to 10 carbon atoms, such as a propargyl group, and a 3-pentynyl group; an aryl group, preferably having 6 to 30 carbon atoms, more preferably 6 to 20 carbon atoms, even more preferably 6 to 12 carbon atoms, such as a phenyl group, a p-methylphenyl group, a naphthyl group, and an anthranil group; an amino group, preferably having 0 to 30 carbon atoms, more preferably 0 to 20 carbon atoms, even more preferably 0 to 10 carbon atoms, such as an amino group, a methylamino group, a dimethylamino group, a diethylamino group, a dibenzyl amino group, a diphenylamino group, and a ditolylamino group; an alkoxy group, preferably having 1 to 30 carbon atoms, more preferably 1 to 20 carbon atoms, even more preferably 1 to 10 carbon atoms, such as a methoxy group, an ethoxy group, a butoxy group, and a 2-ethylhexysiloxy group; an aryloxy group, preferably having 6 to 30 carbon atoms, more preferably 6 to 20 carbon atoms, even more preferably 6 to 12 carbon atoms, such as a phenyloxy group, a 1-naphthyloxy group, and a 2-naphthyloxy group; a heterocyclic oxy group, preferably having 1 to 30 carbon atoms, preferably 1 to 20 carbon atoms, even more preferably 1 to 12 carbon atoms, such as a pyridyloxy group, a pyradyloxy group, a pyrimidyloxy group, and a quinolyloxy group; an acyl group, preferably having 1 to 30 carbon atoms, more preferably 1 to 20 carbon atoms, even more preferably 1 to 12 carbon atoms, such as an acetyl group, a benzoyl group, a formyl group, and a pivaloyl group; an alkoxy carbonyl group, preferably having 2 to 30 carbon atoms, more preferably 2 to 20 carbon atoms, even more preferably 2 to 12 carbon atoms, such as a methoxy carbonyl group, and a ethoxy carbonyl group; an aryloxy carbonyl group, preferably having 7 to 30 carbon atoms, more preferably 7 to 20 carbon atoms, even more preferably 7 to 12 carbon atoms, such as a phenyloxy carbonyl group; an acyloxy group, preferably having 2 to 30 carbon atoms, more preferably 2 to 20 carbon atoms, even more preferably 2 to 10 carbon atoms, such as an acetoxy group and a benzoyloxy group; an acylamino group, preferably having 2 to 30 carbon atoms, more preferably 2 to 20 carbon atoms, even more preferably 2 to 10 carbon atoms, such as an acetylamino group, and a benzoylamino group; an alkoxycarbonyl amino group, preferably having 2 to 30 carbon atoms, more preferably 2 to 20 carbon atoms, even more preferably 2 to 12 carbon atoms, such as a methoxycarbonyl amino group; an aryloxycarbonyl amino group, preferably having 7 to 30 carbon atoms, more preferably 7 to 20 carbon atoms, even more preferably 7 to 12 carbon toms, such as a phenyloxycarbonyl amino group; a sulfonyl amino group, preferably having 1 to 30 carbon atoms, more preferably 1 to 20 carbon atoms, even more preferably 1 to 12 carbon atoms, such as a methane sulfonyl amino group, and a benzene sulfonyl amino group; a sulfamoyl group, preferably having 0 to 30 carbon atoms, more preferably 0 to 20 carbon atoms, even more preferably 0 to 12 carbon atoms, such as a sulfamoyl group, a methylsulfamoyl group, a dimethylsulfamoyl group, and a phenylsulfamoyl group; a carbamoyl group, preferably having 1 to 30 carbon atoms, more preferably 1 to 20 carbon atoms, even more preferably 1 to 12 carbon atoms, such as a carbamoyl group, a methylcarbamoyl group, a diethylcarbamoyl group, and a phenylcarbamoyl group; an alkyl thio group, preferably having 1 to 30 carbon atoms, more preferably 1 to 20 carbon atoms, even more preferably 1 to 12 carbon atoms, such as a methylthio group, and an ethyl thio group; an aryl thio group, preferably having 6 to 30 carbon atoms, more preferably 6 to 20 carbon atoms, even more preferably 6 to 12 carbon atoms, such as a phenyl thio group; a heterocyclic-thio group, preferably having 1 to 30 carbon atoms, more preferably 1 to 20 carbon atoms, even more preferably 1 to 12 carbon atoms, such as a pyridyl thio group, a 2-benzimidazolyl thio group, and a 2-benzoxazolyl thio group, a 2-benzothiazolyl thio; a sulfonyl group, preferably having 1 to 30 carbon atoms, more preferably 1 to 20 carbon atoms, even more preferably 1 to 12 carbon atoms, such as a mesyl group, and a tosyl group; a sulfinyl group, preferably having 1 to 30 carbon atoms, more preferably 1 to 20 carbon atoms, even more preferably 1 to 12 carbon atoms, such as a methane sulfinyl group, and a benzene sulfinyl group; a ureide group, preferably having 1 to 30 carbon atoms, more preferably having 1 to 20 carbon atoms, even more preferably 1 to 12 carbon atoms, such as a ureide group, a methyl ureide group, and a phenyl ureide group; a phosphoric amide group, preferably having 1 to 30 carbon atoms, more preferably 1 to 20 carbon atoms, even more preferably 1 to 12 carbon atoms, such as a diethylphosphoric amide group, and a phenylphosphoric amide group; a hydroxyl group; a mercapto group; a halogen atom, such as a fluorine atom, a chlorine atom, a bromine atom, and a iodine atom; a cyano group; a sulfo group; a carboxyl group; a nitro group; a hydroxamic acid group; a sulfino group; a hydrazino group; an imino group; a heterocyclic group, preferably having 1 to 30 carbon atoms, more preferably 1 to 12 carbon atoms, including nitrogen atoms, oxygen atoms, or sulfur atoms as heteroatoms, such as a imidazolyl group, a pyridyl group, a quinolyl group, a furyl group, a thienyl group, a piperidyl group, a morpholino group, a benzoxazolyl group, a benzimidazolyl group, a benzthiazolyl group, a carbazolyl group, and an azepynyl group; a silyl group, preferably having 3 to 40 carbon atoms, more preferably 3 to 30 carbon atoms, even more preferably 3 to 24 carbon atoms, such as a trimethylsilyl group, and a triphenylsilyl group; and a silyloxy group, preferably having 3 to 40 carbon atoms, more preferably 3 to 30 carbon atoms, even more preferably 3 to 24 carbon atoms, such as a trimethylsilyloxy group, and a triphenylsilyloxy group. These substituents may contain another substituent therein.

Specific examples of the platinum complex compound containing the tetradentate ligand expressed by the general formula 1 include the following compounds, but the examples are not limited to the followings.

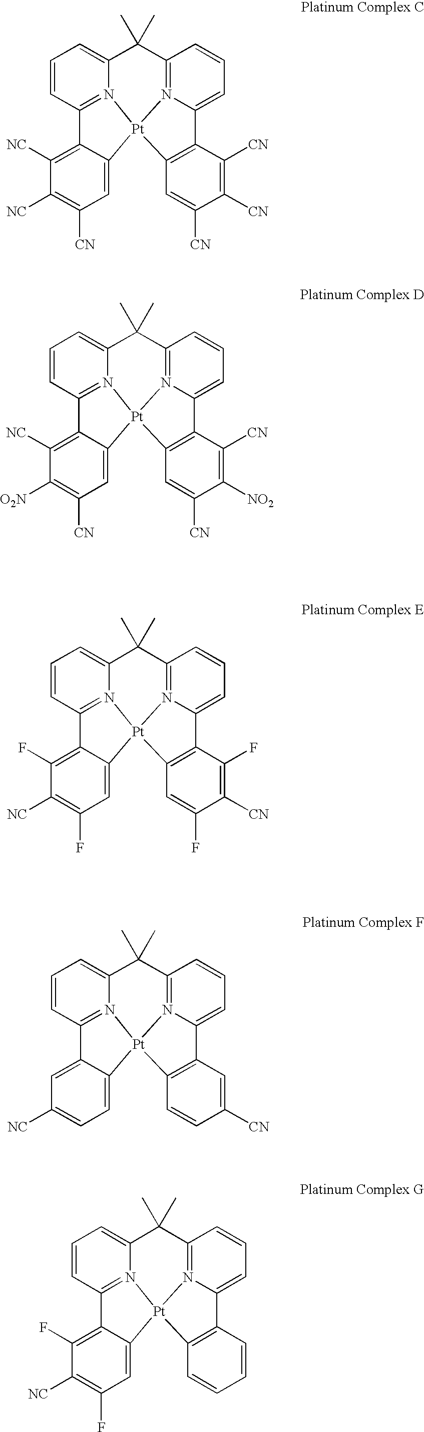

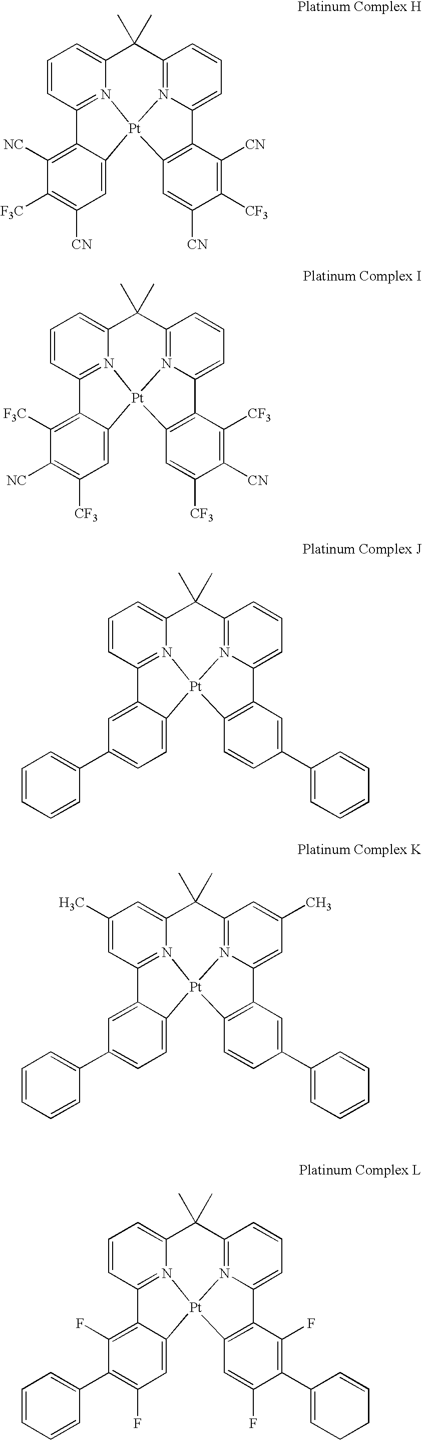

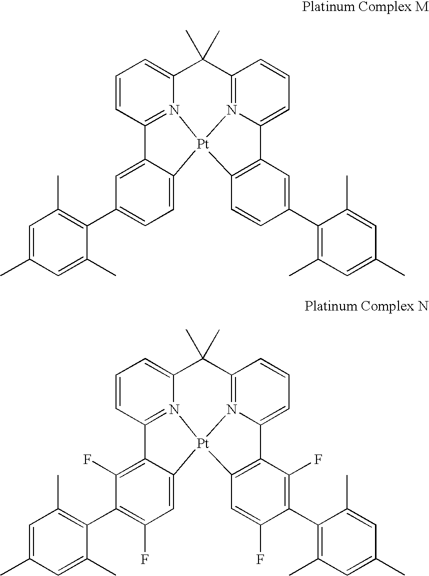

The amount of the platinum complex compound containing the tetradentade ligand, expressed by the general formula 1, is preferably 5% by mass to 99.5% by mass, more preferably 10% by mass to 99.5% by mass, even more preferably 10% by mass to 50% by mass, relative to the total amount of all the compounds contained in the light emitting layer.

When the amount thereof is less than 5% by mass, the effect of voltage reduction may decline.

### —Hole-Transporting Host Material—

The hole-transporting host material may be suitably selected depending on the intended purpose without any restriction. Examples thereof include pyrrole, indole, carbazole, azaindole, azacarbazole, pyrazole, imidazole, polyaryl alkane, pyrazoline, pyrazolone, phenylenediamine, arylamine, amino-substituted chalcone, styrylanthracene, fluorenone, hydrazone, stilbene, silazane, atomatic tertiary amine compound, styrylamine compound, aromatic dimethylidine compound, porphyrin compound, polysilane compound, poly(N-vinyl carbazole), aniline copolymer, high-molecular weight conductive oligomer, such as thiophene oilomer and polythiophene, organic silane, carbon film, and derivatives thereof.

Among them, indole derivatives, carbazole derivatives, azaindole derivatives, azacarbazole derivatives, aromatic tertiary amine compounds and thiophene derivatives are preferable, and those containing a plurality of insole structures, carbazole structures, azaindole structures, azacarbazole structures, or atomatic tertiary amine structures per molecule are particularly preferable.

Moreover, as the host material for use in the present invention, a host material in which part of or all of the hydrogen atoms contained therein are substituted with deuterium may be used (see JP-A Nos. 2009-277790, and 2004-515506).

Specific examples of such hole-transporting host material include the following compounds, but not limited thereto.

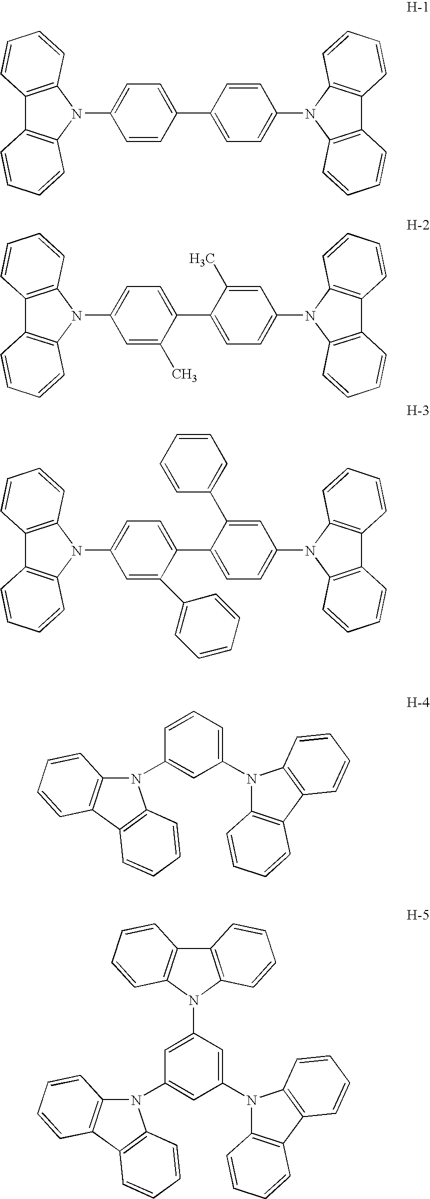

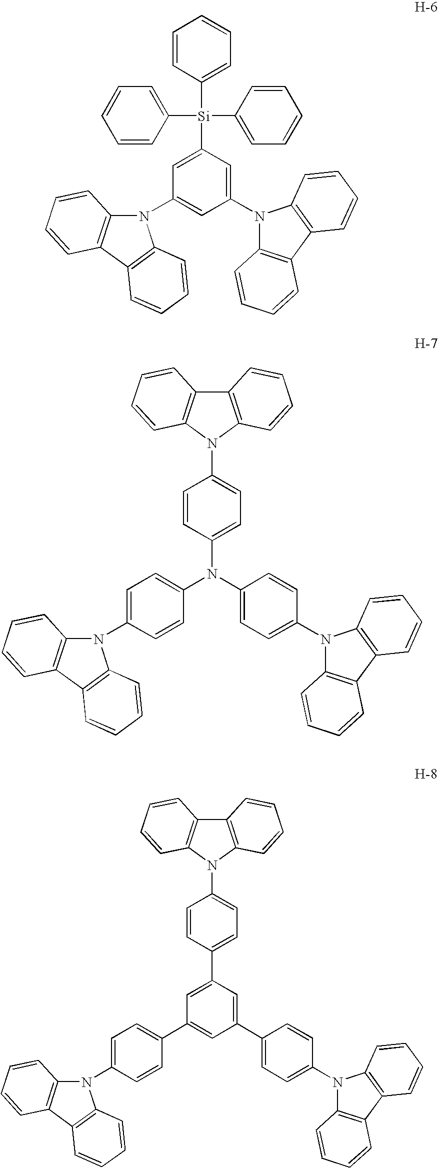

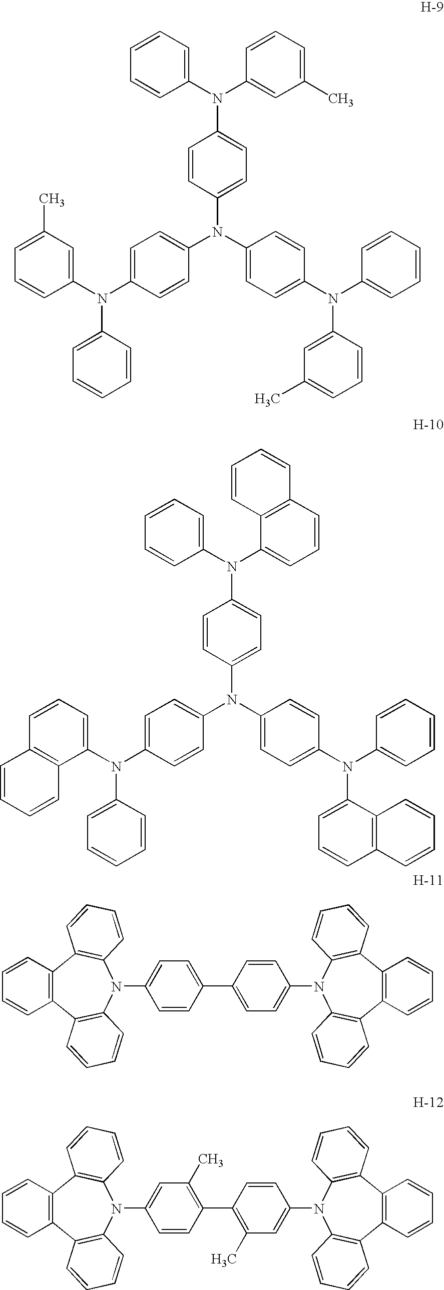

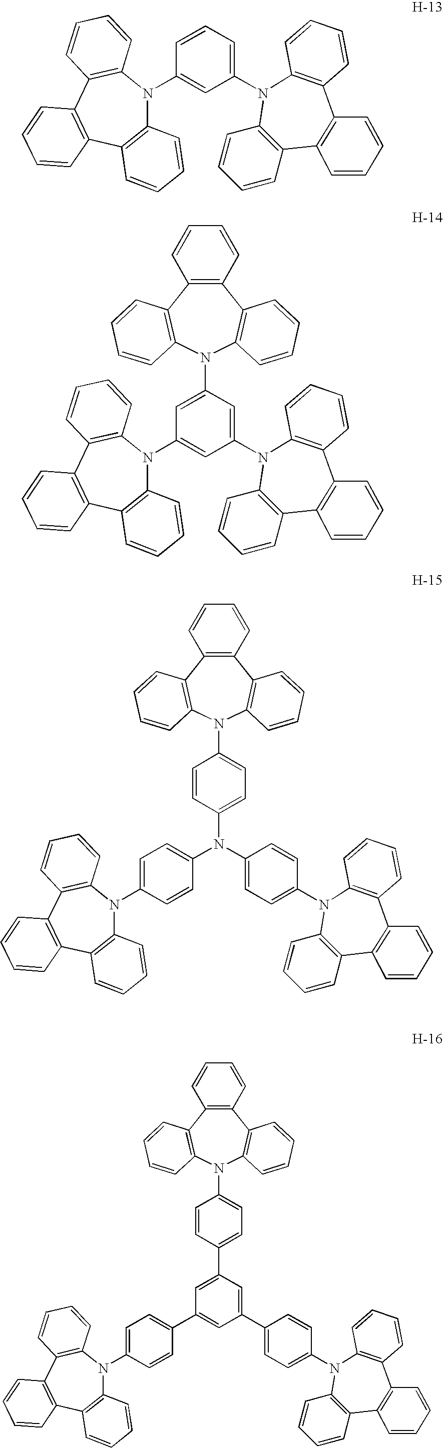

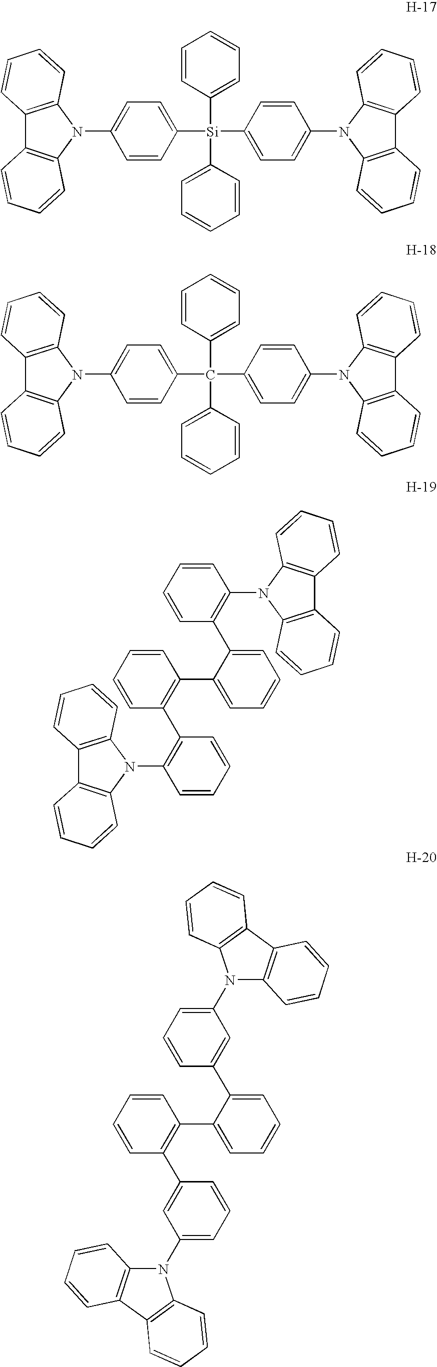

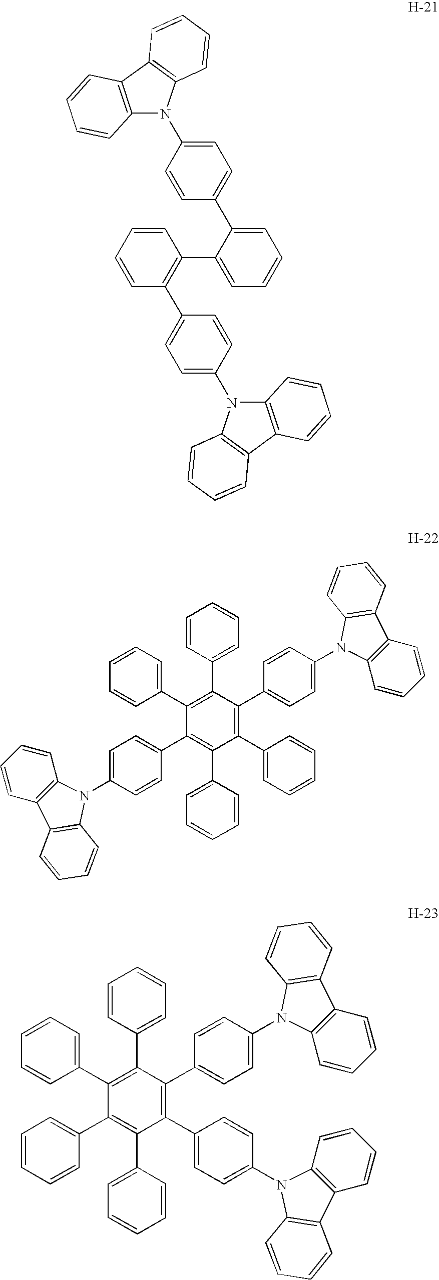

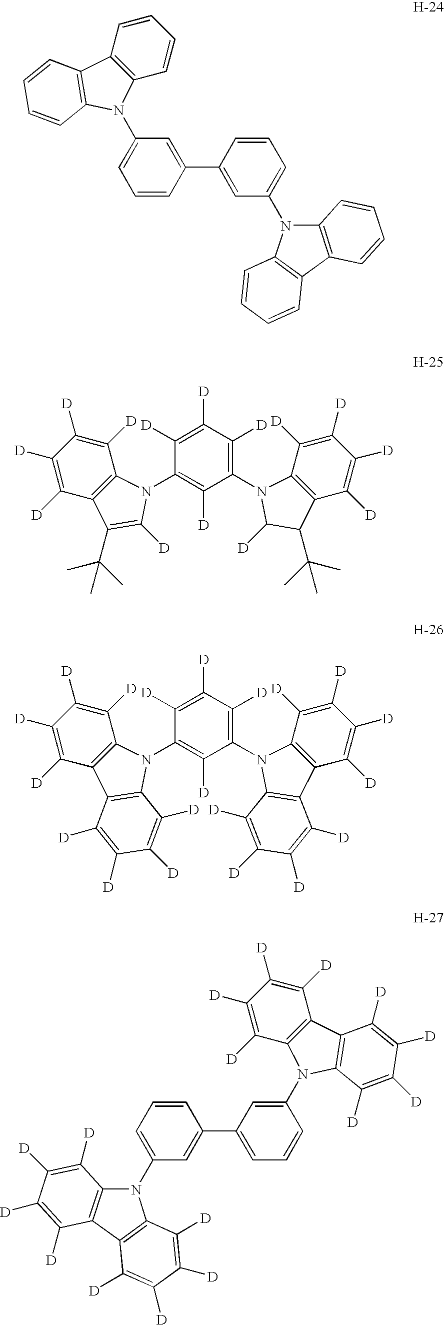

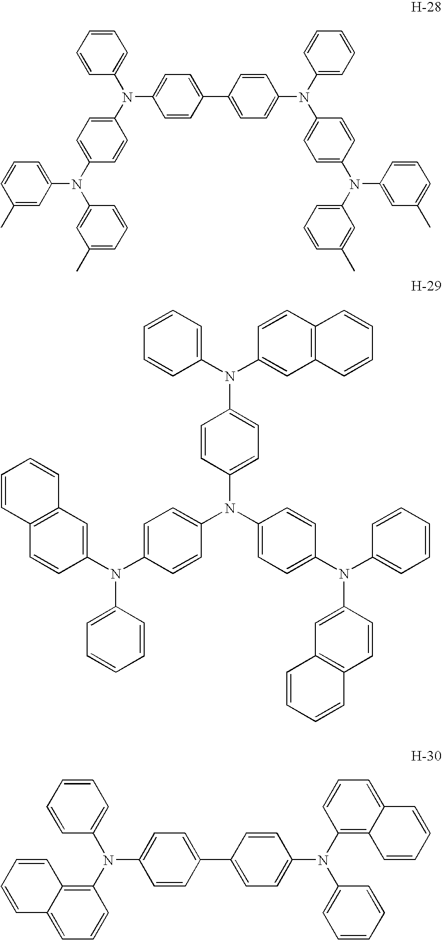

The amount of the hole-transporting host material is preferably 10% by mass to 99% by mass, more preferably 10% by mass to 90% by mass, even more preferably 20% by mass to 90% by mass, relative to the total amount of all the compounds contained in the light-emitting layer.

### <Phosphorescent Light-Emitting Material>

As the phosphorescent light-emitting material, a complex containing a transition metal atom or a lanthanoid atom is generally used. Examples of the transition metal include ruthenium, rhodium, palladium, tungsten, rhenium, osmium, iridium, and platinum. Among them, rhenium, iridium, and platinum are preferable, iridium and platinum being more preferable.

Examples of the lanthanoid atom include lanthanum, cerium, praseodymium, neodymium, samarium, europium, gadolinium, teibium, dysprosium, holmium, erbium, thulium, ytterbium, and lutetecium. Among them, neodymium, europium, and gadolinium are particularly preferable.

Examples of the ligand of the complex include ligands disclosed in G. Wilkinson et al., Comprehensive Coordination Chemistry, Pergamon Press, 1987; H. Yersin, Photochemistry and Photophysics of Coordination Compounds, Springer-Verlag, 1987; and Akio Yamamoto, Organic Metal Chemistry—Foundation and Application, Shokado Publishing Co., Ltd., 1982.

Specific example of the ligand include: a halogen ligand, preferably a chlorine ligand; a aromatic carbon ring ligand, such as a cyclopentadienyl anion, a benzene anion, and a naphthyl anion; a nitrogen-containing heterocyclic ligand, such as a phenyl pyridine, a benzoquinoline, a quinolinol, bipyridyl, and a phenanthroline; a diketone ligand, such as a acetyl acetone; a carboxylic acid ligand, such as an acetic acid ligand; an alkolate ligand, such as a phenolate ligand; a carbon monoxide ligand; an isonitrile ligand; and a cyano ligand. Among them, the nitrogen-containing heterocyclic ligand is preferable.

The complex may contain one transition metal in the compound. Alternatively, the complex may be a binuclear complex containing two or more transition metals. In this case, different types of the metal atoms may be contained at the same time. Among them, the following are listed as specific examples of the light-emitting material, but the examples of the light-emitting material are not limited to the following.

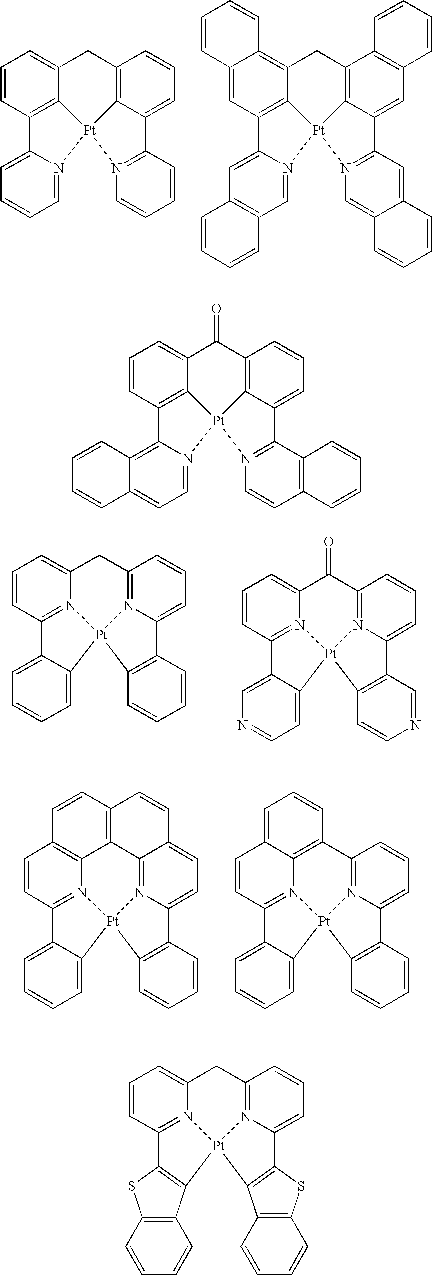

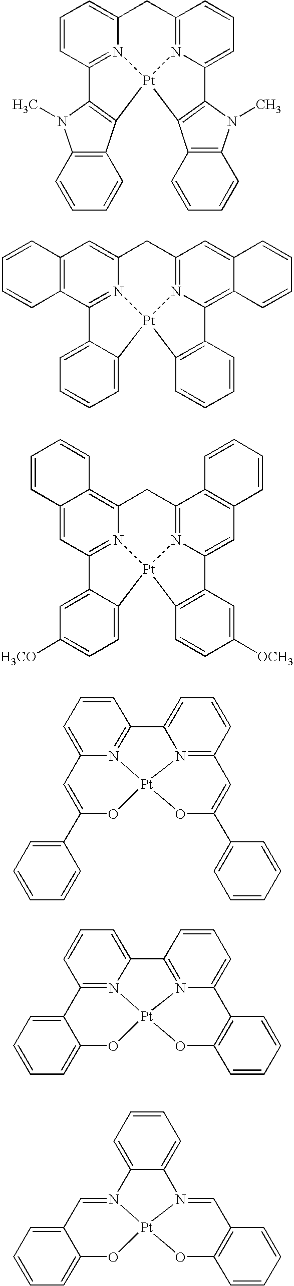

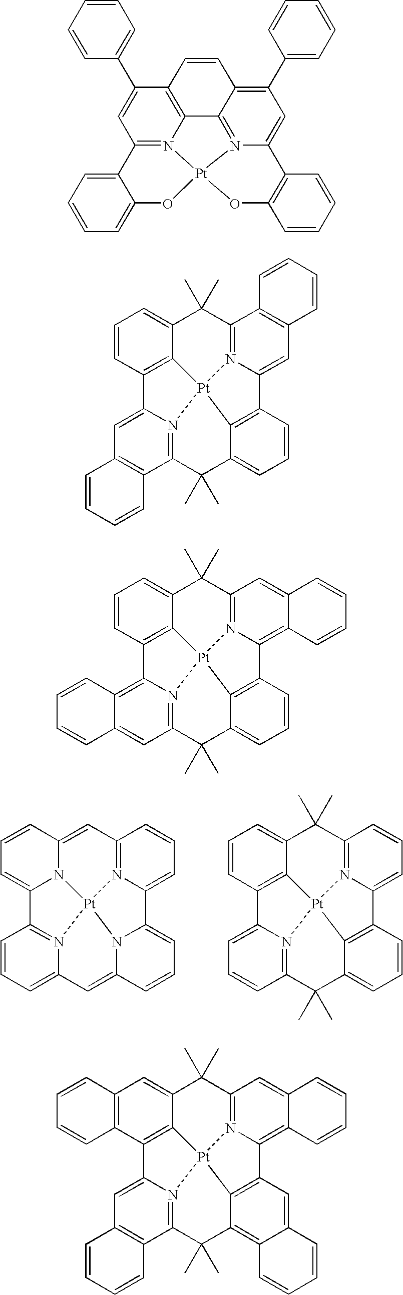

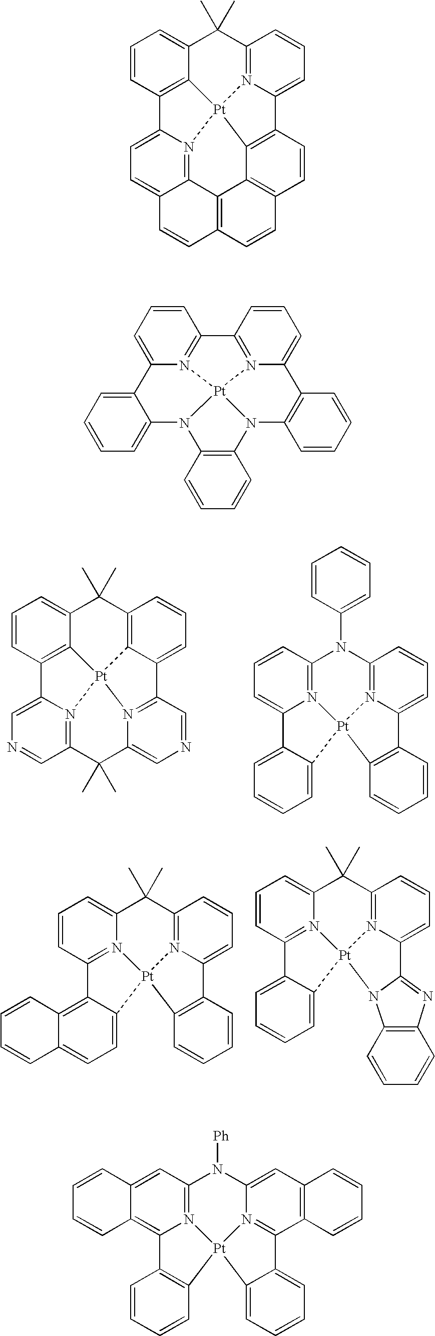

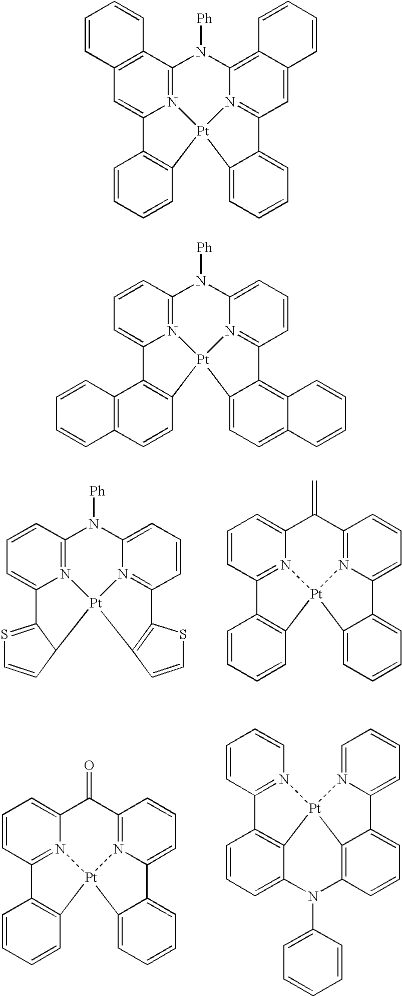

The phosphorescent light-emitting material may be suitably selected depending on the intended purpose without any restriction, but is preferably a compound expressed by any one of the following general formulae 2 to 4:

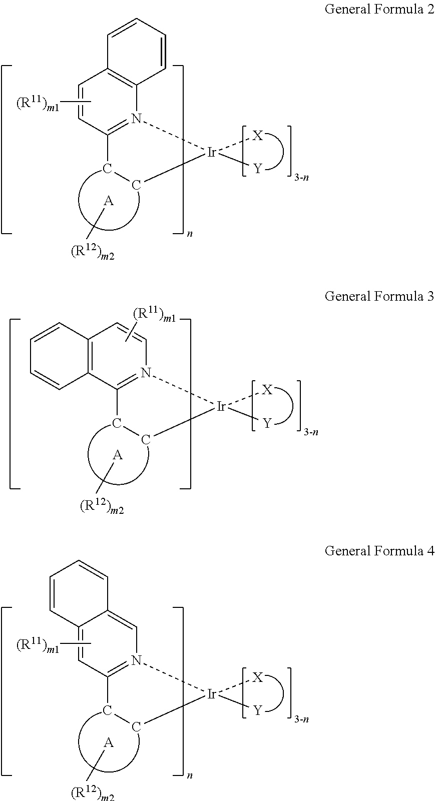

In the general formulae 2 to 4, n is an integer of 1 to 3; X-Y represents a bidentate ligand; a ring A is a ring structure which may contain at least one selected from the group consisting of a nitrogen atom, a sulfur atom, and an oxygen atom; R¹¹ is a substituent, m1 is an integer of 0 to 6, and in the case where m1 is 2 or more, a plurality of R¹¹s adjacent to each other may bond to form a ring, which may contain at least one selected from the group consisting of a nitrogen atom, a sulfur atom, and an oxygen atom, and may further contain one or more substituents; R¹² is a substituent, m2 is an integer of 0 to 4, and in the case where m2 is 2 or more, a plurality of R¹²s adjacent to each other may bond to form a ring, which may contain at least one selected from the group consisting of a nitrogen atom, a sulfur atom, and an oxygen atom, the ring may contain a substituent; R¹¹ and R¹² may bond to each other to form a ring, which may contain at least one selected from the group consisting of a nitrogen atom, a sulfur atom, and an oxygen atom, and may further contain one or more substituents.

The ring A denotes a ring structure, which may contain at least one selected from the group consisting of a nitrogen atom, a sulfur atom, and an oxygen atom, and is preferably a five-member ring, a six-member ring, or the like. The ring may contain one or more substituents.

X-Y denotes a bidentate ligand, and preferable examples thereof include bidentate monoanion ligands, and the like.

Examples of the bidentate monoanion ligand include picolinate (pic), acetylacetonate (acac), and dipicaloylmethanate (t-butyl acac).

Examples of the ligand include, other than listed above, ligands disclosed in International Publication No. WO 02/15645 (Lamansky et al., pp. 89-91).

Substituents denoted as R¹¹ and R¹² may be suitably selected depending on the intended purpose without any restriction. Examples thereof include halogen atoms, alkoxy groups, amino groups, alkyl groups, cycloalkyl groups, aryl groups which may contain a nitrogen atom or sulfur atom, and aryloxy groups which may contain a nitrogen atom or sulfur atom. These substituents may further contain one or more substituents therein.

Adjacent substituents denoted as R¹¹ and R¹² may bond to each other to form a ring that may contain a nitrogen atom, a sulfur atom, or an oxygen atom, and suitable examples of such the ring include a five-member ring and a six-member ring. In addition, such the ring may further contain one or more substituents.

Specific examples of the compound expressed by any of the general formulae 2 to 4 include the following, but are not limited thereto.

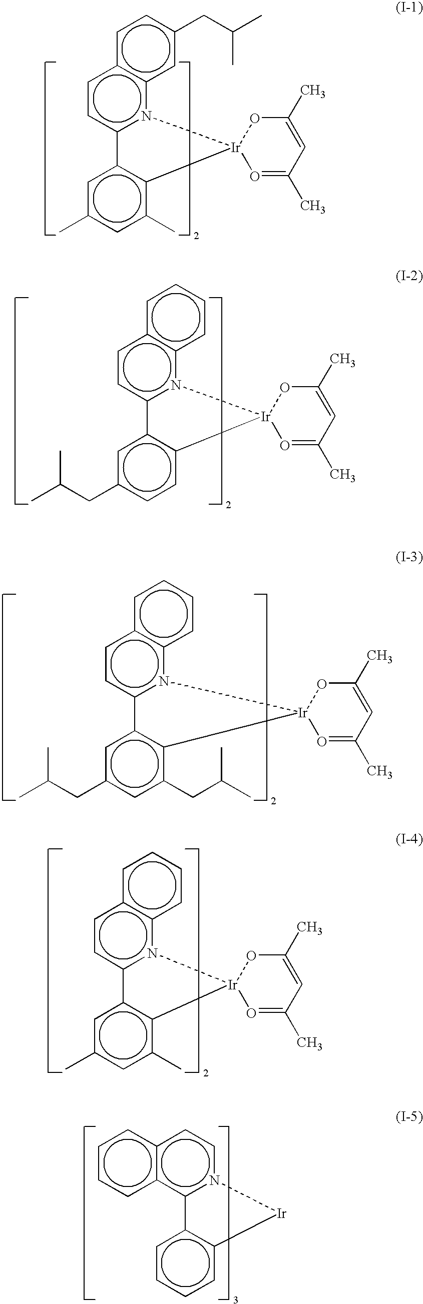

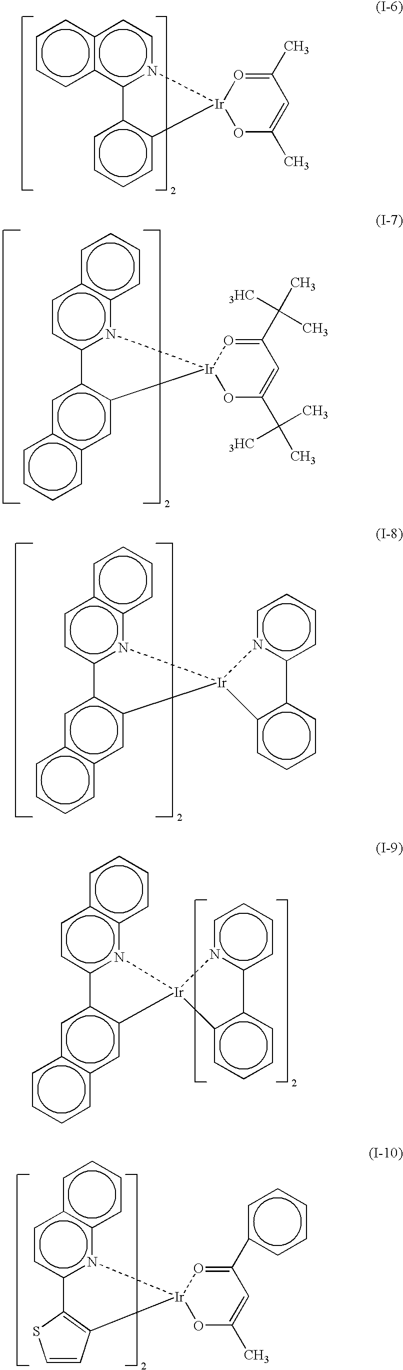

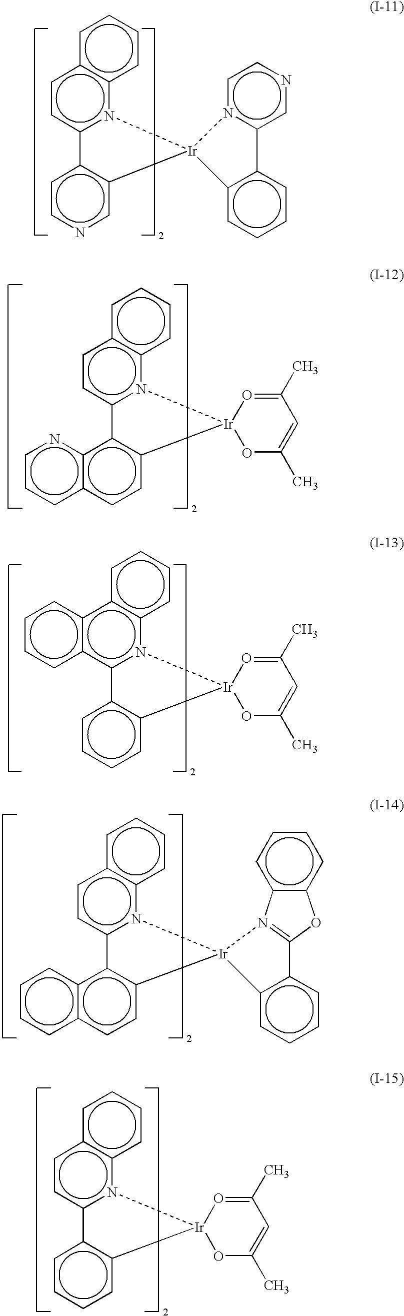

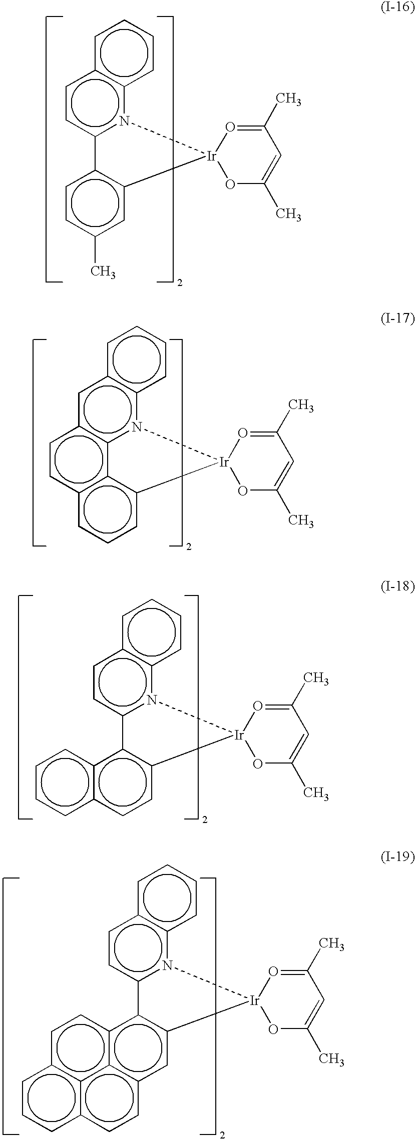

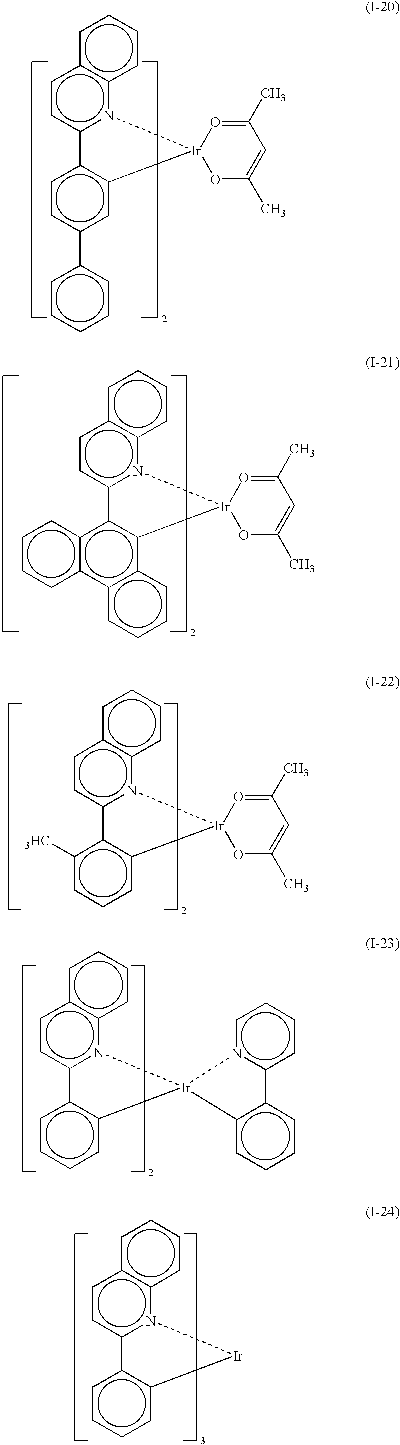

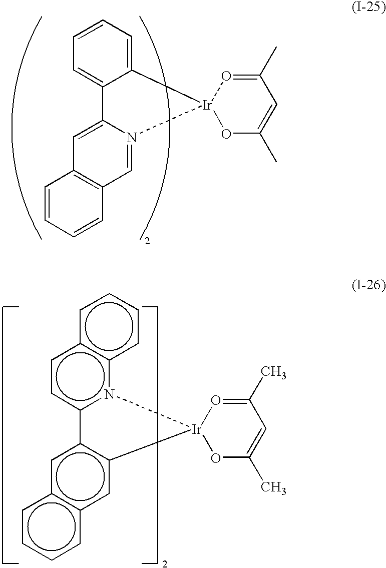

In general, the amount of phosphorescent light-emitting material is preferably 0.5% by mass to 30% by mass, more preferably 0.5% by mass to 20% by mass, more preferably 3% by mass to 10% by mass relative to the total amount of all the compounds contained in the light-emitting layer.

When the amount thereof is less than 0.5% by mass, the emission efficiency may be undesirably low. When the amount thereof is more than 30% by mass, the emission efficiency may be undesirably low due to the aggregations between the phosphorescent light-emitting materials.

The light-emitting layer has the function of receiving holes from the anode, the hole-injection layer, or the hole-transport layer, receiving electrons from the cathode, the electron-injection layer, or the electron-transport layer, and providing a field for recombination of the holes with the electrons for light emission, when an electric field is applied.

The light-emitting layer can be formed by known methods in the art, without any restriction. Preferable examples of the forming method thereof include: dry film-forming methods such as vapor deposition, and sputtering; wet coating; transferring; printing; and inkjet printing.

The thickness of the light-emitting layer may be suitably adjusted depending on the intended purpose without any restriction. The thickness thereof is preferably 2 nm to 500 nm, more preferably 3 nm to 200 nm, even more preferably 10 nm to 200 nm, in view of the emission efficiency. Moreover, the light-emitting layer may be formed of a single layer, or, two or more layers.

The organic electroluminescence element contains an organic layer including the light-emitting layer between an anode and a cathode, and may further contain other layers, if necessary.

The organic layer contains at least the light-emitting layer, an electron-transport layer, and an electron-injection layer, and optionally further contains a hole-injection layer, a hole-transport layer, a hole-blocking layer, an electron-blocking layer, and the like.

### <Electron-Injection Layer and Electron-Transport Layer>

The electron-injection layer and the electron-transport layer both have a function of receiving electrons from the anode side and transport to the cathode side. The electron-injection layer and the electron-transport layer may be of a monolayer structure, or a laminate structure containing a plurality of layers each formed of identical or different compositions.

The electron-injection layer and the electron-transport layer, respectively, may be suitably selected depending on the intended purpose without any restriction. Examples of the material for forming the electron-injection layer and/or the electron-transport layer include: triazole derivative; oxazole derivative; oxadiazole derivative; fluorenone derivative; anthraquinodimehane derivative; anthrone derivative; diphenylquinone derivative; thiopyrandioxide derivative; carbodiimide derivative; fluorenylidenemethane derivative; distyrylpyradine derivative; heterocyclic carboxylic acid anhydride such as naphthalene and perylene; phthalocyanine derivative; metal complex such as 8-quinolinol derivative; metal phthalocyanine; and metal complex containing benzoxazole or benzothiazole as a ligand.

The electron-injection layer and the electron-transport layer may contain a hole-accepting dopant, respectively.

The hole-accepting dopant may be an inorganic compound or an organic compound, provided that it accepts holes, and has a function of reducing organic compounds.

The inorganic compound may be suitably selected depending on the intended purpose without any restriction. Examples thereof include alkali metals, alkaline earth metals, and metal oxides thereof.

The electron-injection layer and the electron-transport layer each preferably have a thickness of 1 nm to 5 μm, more preferably 5 nm to 1 μm, even more preferably 10 nm to 500 nm.

### <Hole-Injection Layer and Hole-Transport Layer>

The hole-injection layer and the hole-transport layer each have a function of receiving holes from the anode or the anode side and transporting to the cathode side. The hole-injection layer and the hole-transport layer may be of a monolayer structure, or a laminate structure containing a plurality of layers each formed of identical or different compositions.

The hole-injection material or hole-transport material used for these layers may be a low-molecular-weight compound or a high-molecular-weight compound.

The hole-injection material or the hole-transport material may be suitably selected depending on the intended purpose without any restriction. Examples thereof include pyrrole derivatives, carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidine compounds, phthalocyanine compounds, porphyrin compounds, thiophene derivatives, organosilane derivatives and carbon. These may be used independently or in combination.

The hole-injection layer and the hole-transport layer, respectively, may contain an electron-accepting dopant.

The electron-accepting dopant may be an inorganic compound or an organic compound, provided that it accepts electrons, and has a function of oxidizing organic compounds.

The inorganic compound is suitably selected depending on the intended purpose without any restriction. Examples thereof include: metal halides, such as ferric chloride, aluminum chloride, gallium chloride, indium chloride and antimony pentachloride; and metal oxides such as vanadium pentaoxide and molybdenum trioxide.

The organic compound may be suitably selected depending on the intended purpose without any restriction. Examples thereof include: those having a substituent such as a nitro group, a halogen atom, a cyano group and a trifluoromethyl group; quinone compounds; acid anhydride compounds; and fullerenes.

These electron-accepting dopants may be used independently, or in combination.

The amount of the electron-accepting dopant is not restricted, though it may vary depending on the types of the materials thereof. The amount thereof is preferably 0.01% by mass to 50% by mass, more preferably 0.05% by mass to 30% by mass, even more preferably 0.1% by mass to 30% by mass relative to the amount of the hole-transport material or hole-injection material.

The hole-injection layer and the hole-transport layer may be formed by known methods in the art, without any restriction. Preferable examples of forming methods thereof include: dry film-forming methods such as vapor deposition and sputtering; wet film-forming methods; transferring; printing; and ink-jet printing.

The hole-injection layer and the hole-transport layer preferably each have a thickness of 1 nm to 500 nm, more preferably 5 nm to 250 nm, yet more preferably 10 nm to 200 nm.

### <Hole-Blocking Layer and Electron-Blocking Layer>

The hole-blocking layer has a function of preventing holes transported from the anode side to the light-emitting layer from passing through to the cathode side, and is generally provided as an organic layer adjacent to the light-emitting layer on the cathode side.

The electron-blocking layer has the function to prevent the electrons transported from the cathode side to the light-emitting layer from passing through to the anode side, and is generally provided as an organic layer adjacent to the light-emitting layer on the anode side.

Examples of the compound for forming the hole-blocking layer include aluminum complexes such as BAlq; triazole derivatives; and phenanthroline derivatives such as BCP.

Examples of the compound for forming the electron-blocking layer are those listed above as the hole-transport material.

The electron-blocking layer and the hole-blocking layer may be formed by known methods in the art, without any restriction. Preferable examples of forming methods thereof include: dry film-forming methods such as vapor deposition and sputtering; wet film-forming methods; transferring; printing; and ink-jet printing.

The hole-blocking layer and the electron-blocking layer each preferably have a thickness of 1 nm to 200 nm, more preferably 1 nm to 50 nm, yet more preferably 3 nm to 10 nm. The hole-blocking layer and the electron-blocking layer may be of a monolayer structure forming of one or more materials mentioned above, or of a laminate structure having a plurality of layers each formed of identical or different compositions.

### <Electrode>

The organic electroluminescence element contains a pair of electrodes; i.e., an anode and a cathode. In consideration of the characteristics of the organic electroluminescence element, at least one of the anode and the cathode is preferably transparent. In general, the anode may serve as an electrode which supplies holes to an organic layer, and the cathode may serve as an electrode which injects electrons into an organic layer.

In terms of the shape, structure, size and the like, the electrode may be suitably selected from the electrode materials known in the art depending on the use of the organic electroluminescence element, without any restriction.

Suitably examples of the material for forming the electrode include metals, alloys, metal oxides, conductive compounds, and mixtures thereof.

### -Anode-

Examples of the material for forming the anode include; conductive metal oxides such as tin oxides doped with, for example, antimony and fluorine (ATO and FTO); tin oxide, zinc oxide, indium oxide, indium tin oxide (ITO) and indium zinc oxide (IZO); metals such as gold, silver, chromium and nickel; mixtures or laminates of these metals and the conductive metal oxides; inorganic conductive materials such as copper iodide and copper sulfide; organic conductive materials such as polyaniline, polythiophene and polypyrrole; and laminates of these materials and ITO. Among them, conductive metal oxides are preferable. In particular, ITO is preferable for its productivity, high conductivity, and transparency.

### -Cathode-

Examples of the material for forming the cathode include alkali metals (e.g., Li, Na, K and Cs), alkaline earth metals (e.g., Mg and Ca), gold, silver, lead, aluminum, sodium-potassium alloys, lithium-aluminum alloys, magnesium-silver alloys and rare earth metals (e.g., indium and ytterbium). These may be used independently, but preferably in combination for the purpose of favorable stability and electron-injection properties.

Among them, alkali metals and alkaline earth metals are preferable in terms of the electron-injection properties, and the material containing aluminum as a main component is preferable in terms of excellent storage stability.

The phrase “material containing aluminum as a main component” refers to a material composed of aluminum alone; alloys containing aluminum and 0.01% by mass to 10% by mass of an alkali or alkaline earth metal; or the mixtures thereof (e.g., lithium-aluminum alloys and magnesium-aluminum alloys).

The electrode can be formed by known methods in the art, without any restriction. Examples of forming methods of the electrode include: wet methods such as printing and coating; physical methods such as vacuum deposition, sputtering, and ion plating; and chemical methods such as CVD, and plasma CDV. According to a method appropriately selected from these methods in consideration of suitability for the material constituting the anode, the anode can be formed on a substrate. For example, when ITO is used as the material for the anode, the anode may be formed with DC or high-frequency sputtering methods, vacuum deposition methods, or ion plating methods. Notably, when metals are used as a material for the below-described cathode, the cathode can be formed by, for example, sputtering one type of metal, or, two or more types of metals simultaneously or sequentially.

Patterning for forming the anode may be performed by a chemical etching method such as photolithography; a physical etching method such as etching by laser; a method of vacuum deposition or sputtering using a mask; a lift-off method; or a printing method.

### <Substrate>

The organic electroluminescence element is preferably provided on a substrate. The organic electroluminescence element may be provided so that the electrode thereof is in direct contact with the substrate, or so that the electrode is in contact with the substrate via an intermediate layer.

The material for the substrate may be suitably selected depending on the intended purpose without any restriction. Examples thereof include inorganic materials such as yttria-stabilized zirconia (YSZ) and glass (alkali-free glass and soda-lime glass); and organic materials such as polyesters (e.g., polyethylene terephthalate, polybutylene phthalate and polyethylene naphthalate), polystyrene, polycarbonate, polyether sulfone, polyarylate, polyimide, polycycloolefin, norbornene resins and poly(chlorotrifluoroethylene).

In terms of the shape, structure, size and the like, the substrate may be suitably adjusted depending on the use, purpose, and the like of the electroluminescence element, without any restriction. In general, it is preferable to provide the substrate in the form of a sheet. The substrate may have a single- or multi-layered structure, and may be a single member or a combination of two or more members. The substrate may be opaque, colorless transparent, or colored transparent.

The substrate may be provided with a moisture permeation-preventing layer (gas barrier layer) on the front and/or back surface thereof.

The moisture permeation-preventing layer (gas barrier layer) is preferably made from an inorganic compound such as silicon nitride and silicon oxide.

The moisture permeation-preventing layer (gas barrier layer) can be formed through, for example, high-frequency sputtering.

### -Protective Layer-

The entire organic electroluminescence element may be protected with a protective layer.

The materials contained in the protective layer may be suitably selected depending on the intended purpose without any restriction, provided that the resulted protective layer will have the function to prevent water, oxygen, and the like, which promote the degradation of the element, from entering into the element. Examples thereof include: metals such as In, Sn, Pb, Au, Cu, Ag, Al, Ti and Ni; metal oxides such as MgO, SiO, SiO₂, Al₂O₃, GeO, NiO, CaO, BaO, Fe₂O₃, Y₂O₃ and TiO₂; metal nitrides such as SiNₓ and SiNₓO_{y}; metal fluorides such as MgF₂, LiF, AlF₃ and CaF₂; polyethylenes, polypropylenes, polymethyl methacrylates, polyimides, polyureas, polytetrafluoroethylenes, polychlorotrifluoroethylens, polydichlorodifluoroethylenes, copolymers of chlorotrifluoroethylens and dichlorodifluoroethylenes, copolymers produced through compolymerization of a monomer mixture containing tetrafluoroethylene and at least one comonomer, fluorine-containing copolymers containing a ring structure in the copolymerization main chain, water-absorbing materials each having a water absorption rate of 1% or more, and moisture permeation preventive substances each having a water absorption rate of 0.1% or less.

The formation method of the protective layer is suitably selected depending on the intended purpose without any restriction. Examples thereof include vacuum deposition, sputtering, reactive sputtering, molecular beam epitaxial (MBE), cluster ion beam, ion plating, plasma polymerization (high-frequency excitation ion plating), plasma CVD, laser CVD, thermal CVD, gas source CVD, coating, printing and transferring.

### -Seal Container-

The organic electroluminescence element may be entirely sealed with a seal container. Further, a moisture absorbent or an inert liquid may be contained in the space between the seal container and the organic electroluminescence element.

The moisture absorbent is not particularly limited and may be appropriately selected depending on the purpose. Examples thereof include barium oxide, sodium oxide, potassium oxide, calcium oxide, sodium sulfate, calcium sulfate, magnesium sulfate, phosphorus pentaoxide, calcium chloride, magnesium chloride, copper chloride, cesium fluoride, niobium fluoride, calcium bromide, vanadium bromide, molecular sieve, zeolite and magnesium oxide.

The inert liquid is not particularly limited and may be appropriately selected depending on the purpose. Examples thereof include paraffins; liquid paraffins; fluorine-containing solvents such as perfluoroalkanes, perfluoroamines and perfluoroethers; chlorinated solvents; and silicone oils.

### -Resin Seal Layer-

The organic electroluminescence element is preferably sealed with a resin seal layer so as to prevent degradation thereof due to oxygen and/or moisture contained in the air.

The resin material for the resin seal layer may be suitably selected depending on the intended purpose without any restriction. Examples thereof include acrylic resins, epoxy resins, fluorine-containing resins, silicone resins, rubber resins and ester resins. Among them, epoxy resins are preferred from the standpoint of its excellent properties in water impermeability. Among the epoxy resins, thermosetting epoxy resins and photo-curable epoxy resins are preferred.

The forming method for the resin seal layer is not particularly limited and may be appropriately selected depending on the purpose. Examples thereof include a method by coating a resin solution, a method by press-bonding or hot press-bonding a resin sheet, and a method by polymerizing under dry conditions (e.g., vapor deposition and sputtering).

### -Sealing Adhesive-

The organic electroluminescence element contains a sealing adhesive having the function of preventing permeation of moisture or oxygen from the edges thereof.

The material for the sealing adhesive may be those used in the resin seal layer. Among them, epoxy resins are preferred from the viewpoint of preventing water permeation, with photo-curable epoxy resins and thermosetting epoxy resins being more preferred.

Also, a filler is preferably added to the sealing adhesive. The filler is preferably inorganic materials such as SiO₂, SiO (silicon oxide), SiON (silicon oxynitride) and SiN (silicon nitride). The filler increases the viscosity of the sealing adhesive to improve processability and humidity resistance.

The sealing adhesive may also contain a desiccant. Examples of the desiccant include barium oxide, calcium oxide or strontium oxide. The amount of the desiccant added to the sealing adhesive is preferably 0.01% by mass to 20% by mass, more preferably 0.05% by mass to 15% by mass. When the amount is less than 0.01% by mass, the desiccant exhibits reduced effects. Whereas when the amount is more than 20% by mass, it may be difficult to homogeneously disperse the desiccant in the sealing adhesive.

In the present invention, the sealing adhesive containing the desiccant is applied in a predetermined amount using, for example, a dispenser. Thereafter, a second substrate is overlaid, followed by curing for sealing.

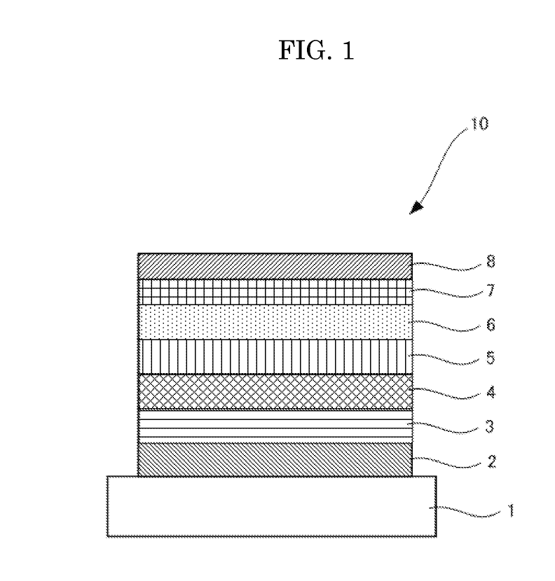

FIG. 1 is a schematic diagram showing one example of the layer structure of the organic electroluminescence element of the invention. The organic EL element 10 has a layer structure in which an anode 2 (e.g., ITO electrode) formed on a glass substrate 1, a hole-injection layer 3, a hole-transport layer 4, a light-emitting layer 5, an electron-transport layer 6, an electron-injection layer 7, and a cathode 8 (e.g., Al—Li electrode) are laminated in this order. Note that, the anode 2 (e.g., ITO electrode) and the cathode 8 (e.g., Al—Li electrode) are connected to each other via a power source.

### -Driving-

The organic electroluminescence element can emit light when a DC voltage (which, if necessary, may contain AC components) (generally 2 volts to 15 volts) or a DC is applied to between the anode and the cathode.

The organic electroluminescence element can be applied to an active matrix by a thin film transistor (TFT). An active layer of the thin film transistor can be formed from, for example, amorphous silicone, high-temperature polysilicone, low-temperature polysilicone, microcrystalline silicone, oxide semiconductor, organic semiconductor or carbon nanotube.

Examples of the thin film transistor applicable in the organic electroluminescence element include those described in, for example, WO2005/088726, JP-A No. 2006-165529, and U.S. Pat. Application Publication No. 2008/0237598 A1.

The light-extraction efficiency of the organic electroluminescence element of the present invention can be improved by various known methods, without any restriction. It is possible to increase the light-extraction efficiency to improve the external quantum efficiency, for example, by processing the surface shape of the substrate (for example, by forming a fine concavo-convex pattern), by controlling the refractive index of the substrate, the ITO layer and/or the organic layer, or by controlling the thickness of the substrate, the ITO layer and/or the organic layer.

The organic electroluminescence element may be used in a top-emission configuration or a bottom-emission configuration, in order for light to be extracted.

The organic electroluminescence element may have a resonator structure. For example, on a transparent substrate are stacked a multi-layered film mirror composed of a plurality of laminated films having different reflective indices, a transparent or semi-transparent electrode, a light-emitting layer and a metal electrode. The light generated in the light-emitting layer is repeatedly reflected between the multi-layered film mirror and the metal electrode (which serve as reflection plates). Therefore, in this matter the light is resonated.

In another preferred embodiment, a transparent or semi-transparent electrode and a metal electrode are stacked on a transparent substrate. In this structure, the light generated in the light-emitting layer is repeatedly reflected between the transparent or semi-transparent electrode and the metal electrode (which serve as reflection plates); i.e., is resonated.

For forming the resonance structure, an optical path length determined based on the effective refractive index of two reflection plates, and on the refractive index and the thickness of each of the layers between the reflection plates is adjusted to be an optimal value for obtaining a desired resonance wavelength. The calculation formula applied in the case of the first embodiment is described in JP-A No. 09-180883. The calculation formula in the case of the second embodiment is described in JP-A No. 2004-127795.

### -Use-

The use of the organic electroluminescence element of the present invention is suitably selected depending on the intended purpose without any restriction. For example, the organic electroluminescence element of the present invention can be suitable used in display elements, displays, backlights, electrophotography, illuminating light sources, recording light sources, exposing light sources, reading light sources, markers, signs, interior accessories and optical communication.

As methods for forming a full color-type organic EL display, there are known, for example (as described in “Monthly Display,” September 2000, pp. 33 to 37), a tricolor light emission method by arranging, on a substrate, organic EL elements emitting lights corresponding to three primary colors (blue color (B), green color (G) and red color (R)); a white color method by separating white light emitted from an organic electroluminescence element for white color emission into three primary colors through a color filter; and a color conversion method by converting a blue light emitted from an organic electroluminescence element for blue light emission into red color (R) and green color (G) through a fluorescent dye layer.

### EXAMPLES

Examples of the present invention will be explained hereinafter, but these examples shall not be construed as to limit the scope of the present invention.

### Comparative Example 1

### Preparation of Organic Electroluminescence Element

A glass substrate having a thickness of 0.5 mm, and a size of 2.5 cm×2.5 cm was placed in a washing container, subjected to ultrasonic washing in 2-propanol, followed by subjected to a UV-ozone treatment for 30 minutes. Onto this glass substrate, the following layers were deposited by vacuum deposition. Note that, in Examples and Comparative Examples, the deposition rate was 0.2 nm/sec., unless otherwise stated. The deposition rate was measured by a crystal resonator. In addition, the thickness of each layer described below was also measured by a crystal resonator.

At first, on the glass substrate, Indium Tin Oxide (ITO) was deposited in the thickness of 100 nm by sputtering as an anode.

Then, on the anode (ITO), α-NPD (bis[N-(1-naphthyl)-N-pheny]benzidine) was deposited in the thickness of 40 nm by vapor deposition, as a hole-transport layer.

On the hole-transport layer, a light-emitting layer was deposited in the thickness of 30 nm by vapor deposition. The light-emitting layer was formed of the platinum complex A expressed by the following structural formula, which served as a host material 1, and the compound (I-15) expressed by the following structural formula, which served as a phosphorescent light-emitting material and provided in an amount of 5% by mass relative to the amount of the host material 1.

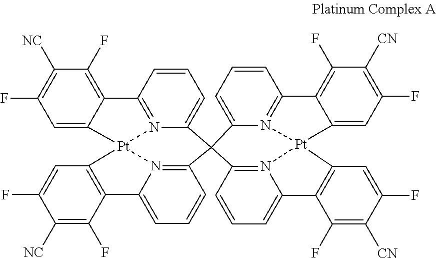

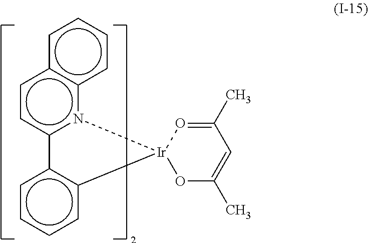

On the light-emitting layer, BAlq (bis-(2-methyl-8-quinolinolato)-4-(phenyl-phenolate)-aluminium (III)) was deposited in the thickness of 55 nm by vapor deposition as an electron-transport layer.

Then, on the electron-transport layer, LiF was deposited in the thickness of 1 nm by vapor deposition, as an electron injection layer.

Next, a patterned mask (the mask to give a pattern having a light-emitting region of 2 mm×2 mm) was placed on the electron injection layer, and aluminum was deposited thereon in the thickness of 100 nm by vapor deposition as a cathode.

The obtained laminate was placed in a glove compartment in which the atmosphere had been replaced with argon gas, and was sealed by using a sealing tin formed of stainless steel and a UV-curable adhesive (XNR5516HV, manufactured by Nagase ChemteX Corporation). In the manner as described above, the organic electroluminescence element of Comparative Example 1 was prepared.

### Comparative Example 2

### Preparation of Organic Electroluminescence Element

The organic electroluminescence element of Comparative Example 2 was prepared in the same manner as Comparative Example 1, provided that the platinum complex A used as the host material 1 in the light-emitting layer was replaced with the platinum complex B expressed by the following structural formula.

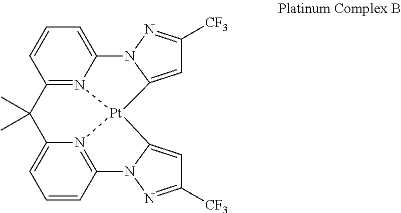

### Example 1

### Preparation of Organic Electroluminescence Element

The organic electroluminescence layer of Example 1 was prepared in the same manner as in Comparative Example 1, provided that the platinum complex A used as the host material 1 in the light-emitting layer was replaced with the platinum complex E expressed by the following structural formula.

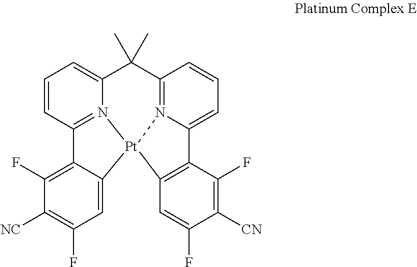

### Example 2

### Preparation of Organic Electroluminescence Element

The organic electroluminescence layer of Example 2 was prepared in the same manner as in Comparative Example 1, provided that the platinum complex A used as the host material 1 in the light-emitting layer was replaced with the platinum complex F expressed by the following structural formula.

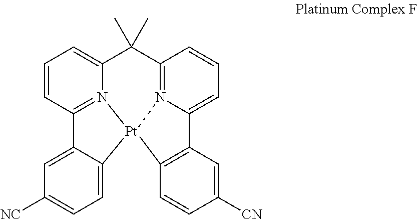

### Example 3

### Preparation of Organic Electroluminescence Element

The organic electroluminescence layer of Example 3 was prepared in the same manner as in Comparative Example 1, provided that the platinum complex A used as the host material 1 in the light-emitting layer was replaced with the platinum complex J expressed by the following structural formula.

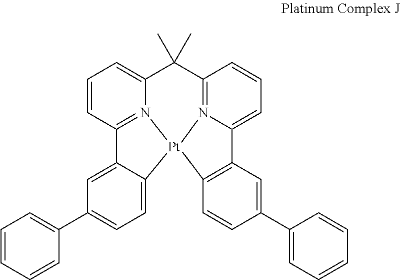

### Example 4

### Preparation of Organic Electroluminescence Element

The organic electroluminescence layer of Example 4 was prepared in the same manner as in Comparative Example 1, provided that the platinum complex A used as the host material 1 in the light-emitting layer was replaced with the platinum complex K expressed by the following structural formula.

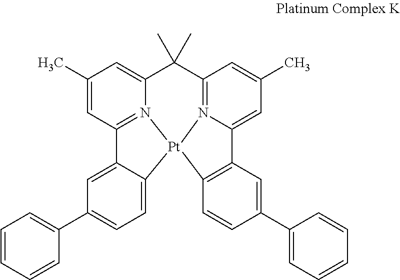

### Comparative Example 3

The organic electroluminescence element of Comparative Example 3 was prepared in the same manner as Comparative Example 1, provided that the light-emitting layer was replaced with a light-emitting layer containing 20% by mass of BAlq as a host material 1, 75% by mass of the compound (H-24) expressed by the following structural formula as a host material 2, and 5% by mass of the compound (I-15) expressed by the structural formula presented earlier as the phosphorescent light-emitting material.

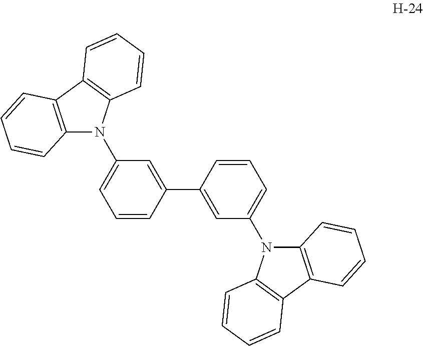

### Comparative Example 4

The organic electroluminescence element of Comparative Example 4 was prepared in the same manner as Comparative Example 1, provided that the light-emitting layer was replaced with a light-emitting layer containing 20% by mass of the aforementioned platinum complex A as a host material 1, 75% by mass of the compound (H-24) expressed by the structural formula presented earlier as a host material 2, and 5% by mass of the compound (I-15) expressed by the structural formula presented earlier as the phosphorescent light-emitting material.

### Example 5

The organic electroluminescence element of Example 5 was prepared in the same manner as Comparative Example 1, provided that the light-emitting layer was replaced with alight-emitting layer containing 20% by mass of the aforementioned platinum complex E as a host material 1, 75% by mass of the compound (H-24) expressed by the structural formula presented earlier as a host material 2, and 5% by mass of the compound (I-15) expressed by the structural formula presented earlier as the phosphorescent light-emitting material.

### Example 6

The organic electroluminescence element of Example 6 was prepared in the same manner as Comparative Example 1, provided that the light-emitting layer was replaced with a light-emitting layer containing 20% by mass of the aforementioned platinum complex F as a host material 1, 75% by mass of the compound (H-24) expressed by the structural formula presented earlier as a host material 2, and 5% by mass of the compound (I-15) expressed by the structural formula presented earlier as the phosphorescent light-emitting material.

The prepared organic electroluminescence elements of Examples 1 to 6 and Comparative Examples 1 to 4 were respectively subjected to the measurements of the driving voltage, external quantum efficiency, and peak wavelength. The results are shown in Tables 1-1 and 1-2.

### <Measurement of Driving Voltage>

A direct voltage was applied to the organic electroluminescence element by a source measure unit 2400 (manufactured by Keithley Instruments Inc.) to allow the organic electroluminescence element to emit, and the voltage at which the current density was 2.5 mA/cm² was measured.

### <Measurement of External Quantum Efficiency>

A direct voltage was applied to the organic electroluminescence element by a source measure unit 2400, manufactured by Keithley Instruments Inc. to allow the organic electroluminescence element to emit. The luminance of the emission was measured by a luminance meter (BM-8, manufactured by Topcon Corporation). The emission spectrum and the emission wavelength were measured by a spectrum analyzer PMA-11, manufactured by Hamamatsu Photonics K.K. Based on these values, the emission efficiency at the current density of 2.5 mA/cm² was calculated as external quantum efficiency in accordance with the luminance conversion method.

### <Measurement of Peak Wavelength>

The peak wavelength was determined from the spectrum obtained by a spectrum analyzer PMA-11, manufactured by Hamamatsu Photonics K.K.

TABLE 1-1

| | | Phosphorescent | | External | |
|---|---|---|---|---|---|
| | | light-emitting | Driving voltage | quantum | Peak |
| | Host material | material | [V] | efficiency [%] | wavelength |
| | (% by mass) | (% by mass) | (at 2.5 mA/cm²) | (at 2.5 mA/cm²) | (nm) |
| Comp. | Platinum | I-15 (5) | 7.2 | 7.6 | 595 |
| Ex. 1 | complex A | | | | |
| | (95) | | | | |
| Comp. | Platinum | I-15 (5) | 7.5 | 6.5 | 594 |
| Ex. 2 | complex B | | | | |
| | (95) | | | | |
| Ex. 1 | Platinum | I-15 (5) | 6.0 | 9.6 | 596 |
| | complex E | | | | |
| | (95) | | | | |
| Ex. 2 | Platinum | I-15 (5) | 6.2 | 9.4 | 595 |
| | complex F | | | | |
| | (95) | | | | |
| Ex. 3 | Platinum | I-15 (5) | 6.4 | 9.8 | 594 |
| | complex J | | | | |
| | (95) | | | | |
| Ex. 4 | Platinum | I-15 (5) | 6.8 | 9.2 | 596 |
| | complex K | | | | |
| | (95) | | | | |

TABLE 1-2

| | | | Phosphorescent | Driving | External | |
|---|---|---|---|---|---|---|
| | Host | Host | light-emitting | voltage | quantum | Peak |
| | material 1 | material 2 | material | [V] | efficiency [%] | wavelength |
| | (% by mass) | (% by mass) | (% by mass) | (at 2.5 mA/cm²) | (at 2.5 mA/cm²) | (nm) |
| Comp. | BAlq (20) | H-24 (75) | I-15 (5) | 8.5 | 10.5 | 595 |
| Ex. 3 | | | | | | |
| Comp. | Platinum | H-24 (75) | I-15 (5) | 7.5 | 12.1 | 595 |
| Ex. 4 | complex A | | | | | |
| | (20) | | | | | |
| Ex. 5 | Platinum | H-24 (75) | I-15 (5) | 6.5 | 13.5 | 596 |
| | complex E | | | | | |
| | (20) | | | | | |
| Ex. 6 | Platinum | H-24 (75) | I-15 (5) | 6.7 | 13.2 | 595 |
| | complex F | | | | | |
| | (20) | | | | | |

Since the organic electroluminescence element of the present invention can realize both reduction in voltage for use and high efficiency, it can be suitably applied in display elements, displays, backlights, electrophotography, illuminating light sources, recording light sources, exposing light sources, reading light sources, markers, signs, interior accessories and optical communication.

What is claimed is:

1. An organic electroluminescence element, comprising:
an anode;
a cathode; and
at least one organic layer disposed between the cathode and the anode, the organic layer comprising a light-emitting layer,
wherein the light-emitting layer contains a host material and a phosphorescent light-emitting material, and the host material contains at least one platinum complex compound containing a tetradentade ligand, expressed by the following general formula 1: 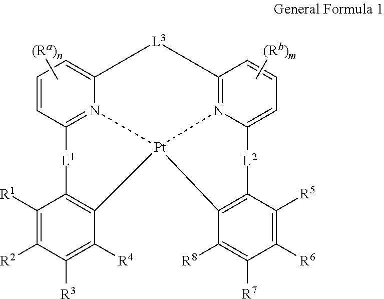
where L¹, L², and L³ are each a single bond or a bridging group; R¹, R², R³, R⁴, R⁵, R⁶, R⁷, and R⁸ are each a hydrogen atom or a substituent, and at least one of R¹ to R⁸ is a phenyl group or a cyano group; R^{a} and R^{b} are each a substituent; and n and m are each an integer of 0 to 3.

2. The organic electroluminescence element according to claim 1, wherein the organic electroluminescence element exhibits a luminescence peak at 550 nm or more.

3. The organic electroluminescence element according to claim 1, wherein the host material contains at least one hole-transporting host material.

4. The organic electroluminescence element according to claim 1, wherein the phosphorescent light-emitting material is a compound expressed by any of the following general formulae 2 to 4: 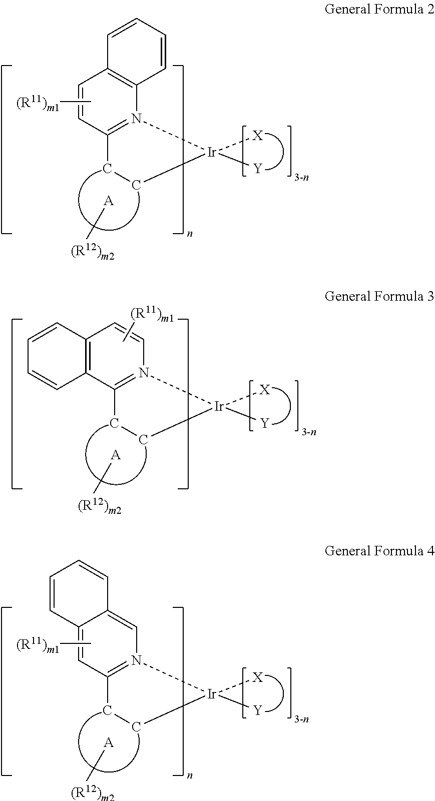
where n is an integer of 1 to 3; X-Y represents a bidentate ligand; a ring A is a ring structure which may contain at least one selected from the group consisting of a nitrogen atom, a sulfur atom, and an oxygen atom; R¹¹ is a substituent, m¹ is an integer of 0 to 6, and in the case where m¹ is 2 or more, a plurality of R¹¹s adjacent to each other may bond to form a ring, which may contain at least one selected from the group consisting of a nitrogen atom, a sulfur atom, and an oxygen atom, and may have further one or more substituents; R¹² is a substituent, m2 is an integer of 0 to 4, and in the case where m2 is 2 or more, a plurality of R¹²s adjacent to each other may bond to form a ring, which may contain at least one selected from the group consisting of a nitrogen atom, a sulfur atom, and an oxygen atom, and may further contain one or more substituents; R¹¹ and R¹² may bond to each other to form a ring, which may contain at least one selected from the group consisting of a nitrogen atom, a sulfur atom, and an oxygen atom, and may further contain one or more substituents.
